(19) United States
(12) Patent Application Publication
(10) Pub. No.: US 2010/0102447 A1
(43) Pub. Date: Apr. 29, 2010

(54) Substrate of window ball grid array package and method for making the same

(76) Inventors: Chih-Yi Huang, Kaohsiung (TW); Hung-Hsiang Cheng, Kaohsiung (TW); Chien-Hao Wang, Kaohsiung (TW)

Correspondence Address: MCCRACKEN & FRANK LLP, 311 S. WACKER DRIVE, SUITE 2500, CHICAGO, IL, 60606, US

(21) Appl. No.: 12/584,094

(22) Filed: Aug. 31, 2009

(30) Foreign Application Priority Data
Oct. 24, 2008 (TW) 097140780

(51) Int. Cl. H01L 23/52; H01L 21/44

(52) U.S. Cl. 257/738; 438/614; 257/E23.141; 257/E21.476

(57) ABSTRACT

The present invention relates to a substrate of a window ball grid array package and a method for making the same. The substrate includes a core layer, a first conductive layer, a second conductive layer, at least one window and at least one via. The window includes a first through hole and a third conductive layer. The first through hole penetrates the substrate and has a first sidewall. The third conductive layer is disposed on the first sidewall and connects the first conductive layer and the second conductive layer. The via includes a second through hole and a fourth conductive layer. The second through hole penetrates the substrate and has a second sidewall. The fourth conductive layer is disposed on the second sidewall and connects the first conductive layer and the second conductive layer. As a result, the substrate has the effect of controlling the characteristic impedance and increasing the signal integrity.

### BACKGROUND OF THE INVENTION

1. Field of the Invention

The present invention relates to a substrate of a package and a method for making the same, and more particularly to a substrate of a window ball grid array package and a method for making the same.

2. Description of the Related Art

FIG. 1 shows a top view of a conventional substrate of a window ball grid array package, wherein a solder mask is omitted. Also, referring to FIGS. 2 and 3, FIG. 2 shows a cross-sectional view along line 2-2 in FIG. 1, wherein solder balls and wires are added; FIG. 3 shows a cross-sectional view along line 3-3 in FIG. 1, wherein solder balls and wires are added. The substrate 1 comprises at least one window 11, a first conductive layer 12, a second conductive layer 13 (as shown in FIGS. 2 and 3), a dielectric layer 14 (as shown in FIGS. 2 and 3), a plurality of first vias 15A and a plurality of second vias 15B.

The window 11 penetrates the substrate 1, and the window 11 is rectangular. The first conductive layer 12 has at least one first power/ground plane 122, a plurality of I/O ball pads 16, a plurality of power/ground ball pads 17, a plurality of fingers (a plurality of first fingers 121A and a plurality of second fingers 121B) and a plurality of conductive traces (a plurality of first conductive traces 18A and a plurality of second conductive traces 18B).

The material of the first power/ground plane 122 is copper. The power/ground ball pads 17 are disposed on the first power/ground plane 122. A plurality of solder balls 19 (as shown in FIGS. 2 and 3) are formed on the I/O ball pads 16 and the power/ground ball pads 17. The fingers (the first fingers 121A and the second fingers 121B) are disposed at the periphery of the window 11, and electrically connected to a chip (not shown) by a plurality of wires 20 (as shown in FIGS. 2 and 3). The first fingers 121A are electrically connected to the I/O ball pads 16 by the first conductive traces 18A. The second fingers 121B are electrically connected to the second vias 15B by the second conductive traces 18B.

The second conductive layer 13 has at least one second power/ground plane 131 (as shown in FIGS. 2 and 3). The material of the second power/ground plane 131 is copper. The dielectric layer 14 is disposed between the first conductive layer 12 and the second conductive layer 13. The first vias 15A penetrate the dielectric layer 14 and electrically connect the first power/ground plane 122 to the second power/ground plane 131. The second vias 15B penetrate the dielectric layer 14 and electrically connect the second conductive traces 18B and the second fingers 121B to the second power/ground plane 131.

FIGS. 2 and 3 show schematic views of the conventional substrate of a window ball grid array package during operation. First, FIG. 2 shows a schematic view of a current of a signal. When the chip (not shown) sends a signal, the signal current is transmitted to the first fingers 121A by the wires 20, and then transmitted to the I/O ball pads 16 by the first conductive traces 18A, and finally transmitted out by the solder balls 19.

FIG. 3 shows a schematic view of a return current. The return current is transmitted to the power/ground ball pads 17 by the solder balls 19, and then transmitted to the second power/ground plane 131 of the second conductive layer 13 by the first power/ground plane 122 of the first conductive layer 12 and the first vias 15A. Afterward, the return current is transmitted to the first conductive layer 12 by the second vias 15B, and then transmitted to the second fingers 121B by the second conductive traces 18B, and finally transmitted back to the chip by the wires 20.

The conventional substrate 1 of a window ball grid array package has the following disadvantages. The second conductive layer 13 is a good conductor with a wide area, which provides a path with low impedance for the return current, and is an ideal reference plane for the signal. However, the second vias 15B are disposed at the periphery of the substrate 1, which is close to the solder balls 19 and far away from the second fingers 121B, and the return current has to be transmitted back to the second conductive traces 18B of the first conductive layer 12 by the second vias 15B, rather than the second conductive layer 13 which provides a path with low impedance. Thus, the return current produces higher impedance, which negatively affects the electrical property of the substrate 1.

Therefore, it is necessary to provide a substrate of a window ball grid array package and a method for making the same to solve the above problems.

### SUMMARY OF THE INVENTION

The present invention is directed to a method for making a substrate of a window ball grid array package. The method comprises the following steps: (a) providing a substrate having a core layer, a first conductive layer and a second conductive layer; (b) forming at least one first through hole and at least one second through hole, wherein the first through hole and the second through hole penetrate the substrate, the first through hole has a first sidewall, and the second through hole has a second sidewall; (c) forming a third conductive layer on the first sidewall and a fourth conductive layer on the second sidewall; (d) patterning the first conductive layer so as to form a first circuit; (e) forming a solder mask on the first conductive layer and the second conductive layer; (f) patterning the solder mask so as to form an opening pattern, wherein the opening pattern exposes part of the first circuit; and (g) forming a plurality of fingers in the opening pattern.

The present invention is further directed to a substrate of a window ball grid array package. The substrate comprises a core layer, a first conductive layer, a second conductive layer, at least one window and at least one via. The core layer has a first surface and a second surface. The first conductive layer is disposed on the first surface of the core layer. The second conductive layer is disposed on the second surface of the core layer. The window comprises a first through hole and a third conductive layer. The first through hole penetrates the core layer, the first conductive layer and the second conductive layer. The first through hole has a first sidewall. The third conductive layer is formed on the first sidewall and connects the first conductive layer and the second conductive layer. The via comprises a second through hole and a fourth conductive layer. The second through hole penetrates the core layer, the first conductive layer and the second conductive layer. The second through hole has a second sidewall. The fourth conductive layer is formed on the second sidewall and connects the first conductive layer and the second conductive layer.

In the present invention, the third conductive layer is disposed on the first sidewall of the first through hole of the window, and electrically connects the second fingers to the second power/ground plane. Since the second conductive layer is a good conductor with a wide area, the return current passes through a path with low impedance on the second conductive layer and then is transmitted to the second fingers by the third conductive layer. As a result, the substrate has the effect of controlling the characteristic impedance and increasing the signal integrity.

### BRIEF DESCRIPTION OF THE DRAWINGS

FIG. 1 is a top view of a conventional substrate of a window ball grid array package, wherein a solder mask is omitted;

FIG. 2 is a cross-sectional view along line 2-2 in FIG. 1, wherein solder balls and wires are added;

FIG. 3 is a cross-sectional view along line 3-3 in FIG. 1, wherein solder balls and wires are added;

FIGS. 4 to 10 are schematic views of a method for making a substrate of a window ball grid array package according to a preferable embodiment of the present invention;

FIG. 11 is a top view of a substrate of a window ball grid array package according to a first embodiment of the present invention, wherein a solder mask is omitted;

FIG. 12 is a cross-sectional view along line 12-12 in FIG. 11, wherein solder balls and wires are added;

FIG. 13 is a cross-sectional view along line 13-13 in FIG. 11, wherein solder balls and wires are added;

FIG. 14 is a top view of a substrate of a window ball grid array package according to a second embodiment of the present invention;

FIG. 15 is a top view of a substrate of a window ball grid array package according to a third embodiment of the present invention; and

FIG. 16 is a top view of a substrate of a window ball grid array package according to a fourth embodiment of the present invention.

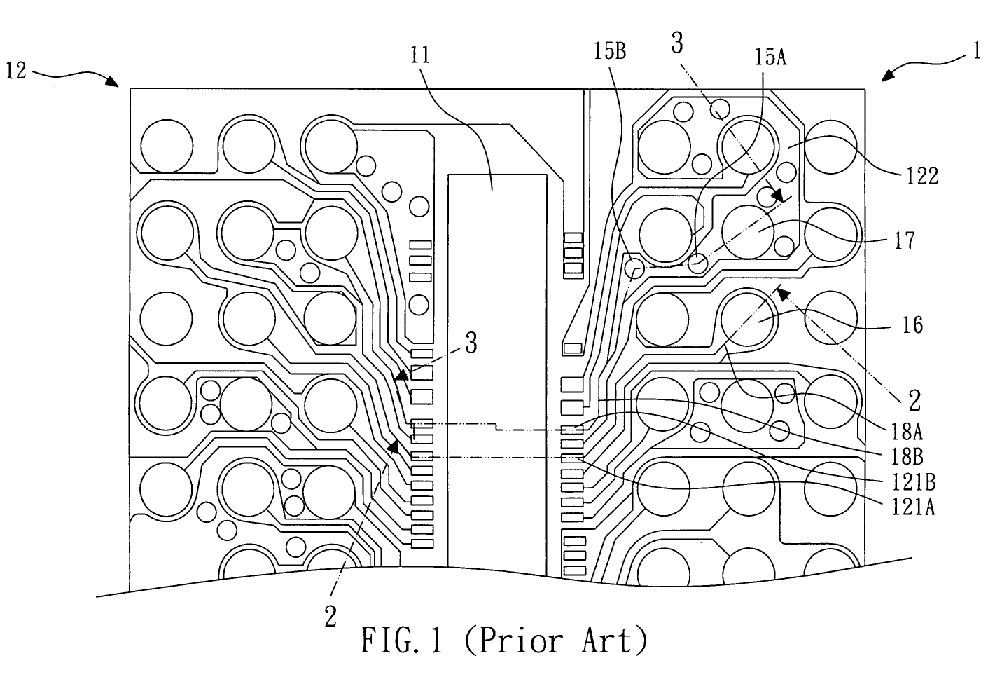

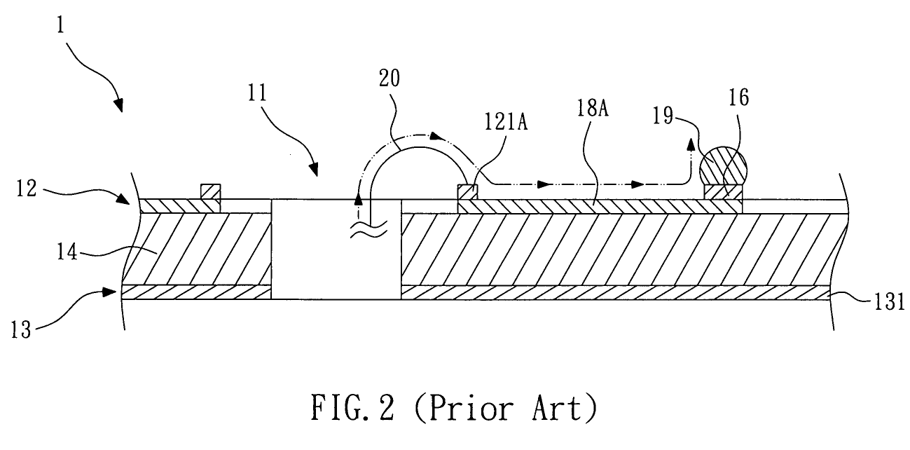

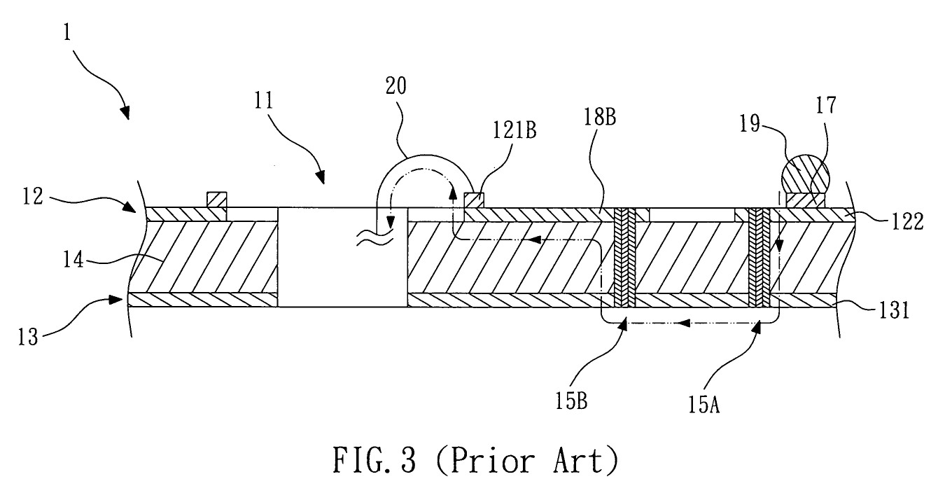

### DETAILED DESCRIPTION OF THE INVENTION

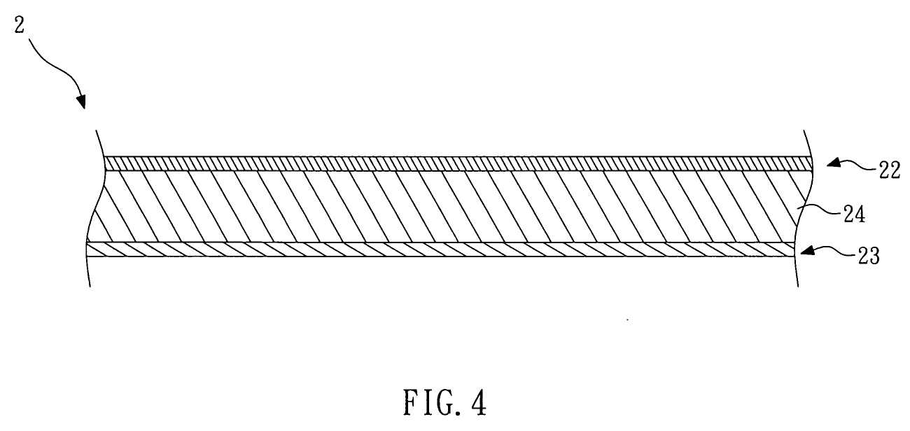

FIGS. 4 to 10 show schematic views of a method for making a substrate of a window ball grid array package according to a preferable embodiment of the present invention. As shown in FIG. 4, a substrate 2 is provided. The substrate 2 has a core layer 24, a first conductive layer 22 and a second conductive layer 23. In the embodiment, the material of the core layer 24 is a dielectric material, and the material of the first conductive layer 22 and the second conductive layer 23 is copper.

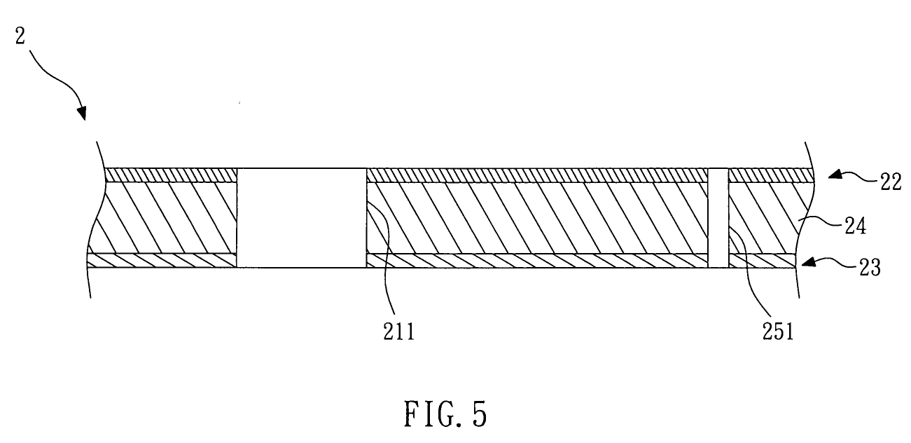

As shown in FIG. 5, at least one first through hole 211 and at least one second through hole 251 are formed. The first through hole 211 and the second through hole 251 penetrate the substrate 2, the first through hole 211 has a first sidewall, and the second through hole 251 has a second sidewall. The first through hole 211 is used for wire bonding to a chip (not shown), and the second through hole 251 is used for interconnection. In the embodiment, the first through hole 211 and the second through hole 251 are formed by drilling, and the diameter of the first through hole 211 is larger than that of the second through hole 251.

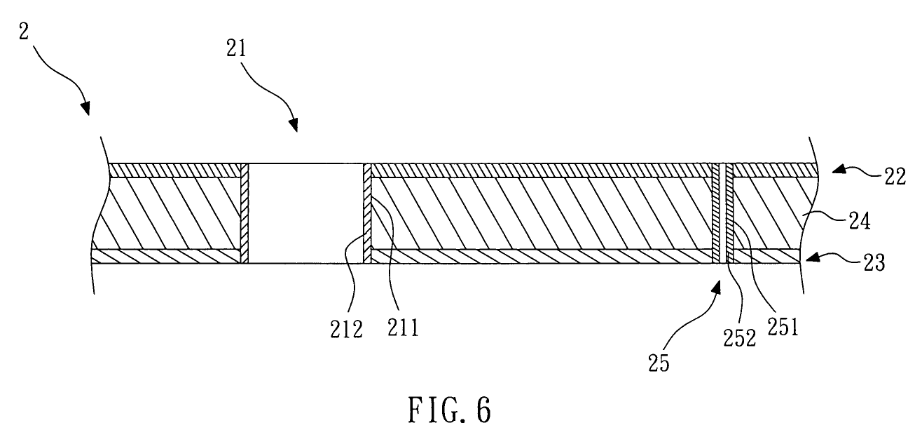

As shown in FIG. 6, a third conductive layer 212 is formed on the first sidewall, and a fourth conductive layer 252 is formed on the second sidewall. In the embodiment, the third conductive layer 212 is formed on the first sidewall by electroplating, and the fourth conductive layer 252 is formed on the second sidewall by electroplating. The third conductive layer 212 connects the first conductive layer 22 and the second conductive layer 23, and the fourth conductive layer 252 also connects the first conductive layer 22 and the second conductive layer 23. Therefore, the first through hole 211 and the third conductive layer 212 form a window 21, and the second through hole 251 and the fourth conductive layer 252 form a via 25. The window 21 is used for wire bonding to the chip (not shown), and the via 25 is used for interconnection.

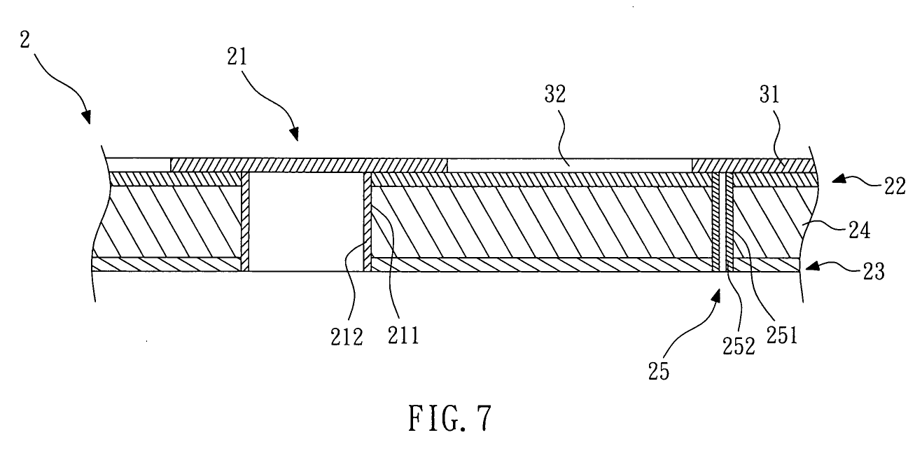

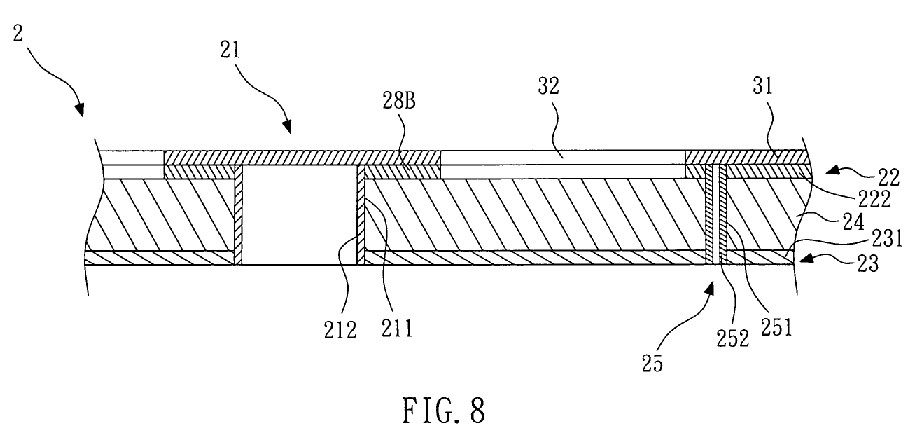

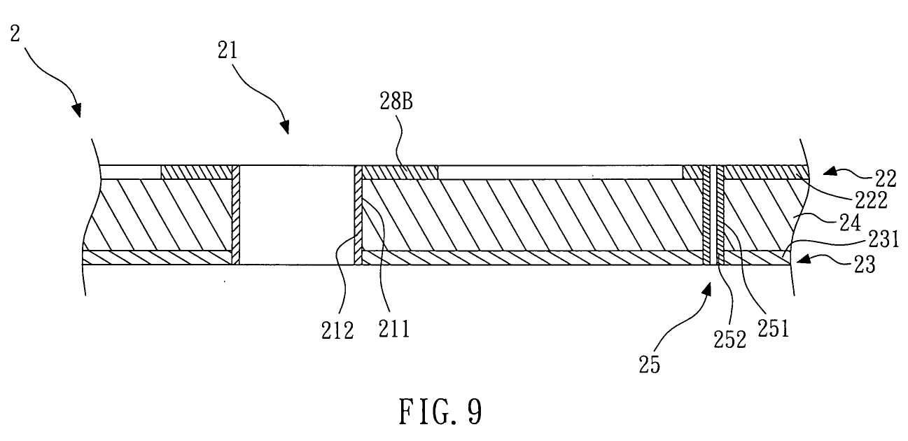

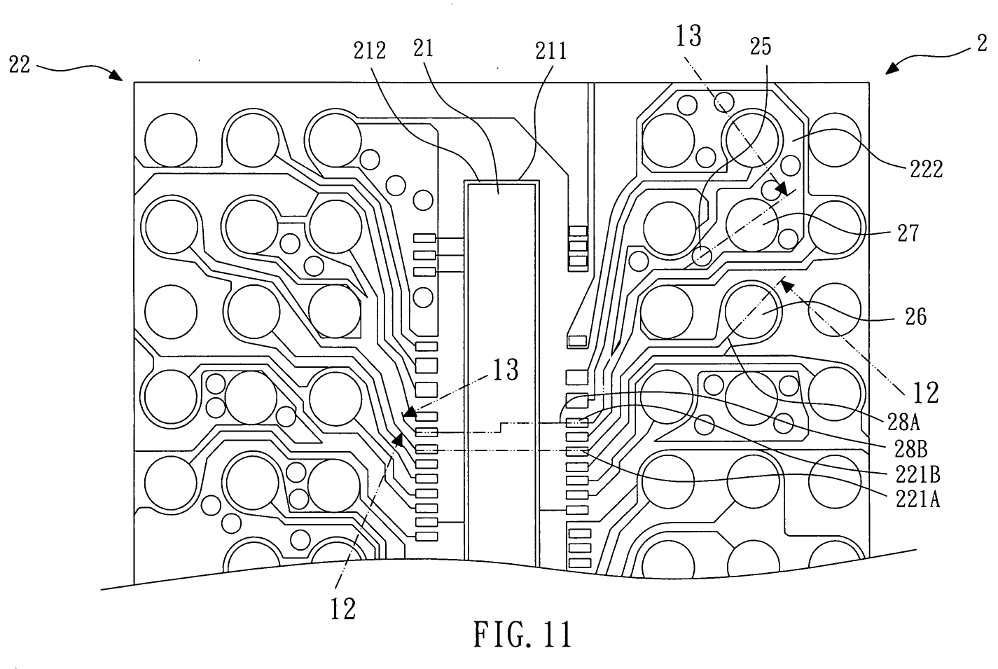

As shown in FIGS. 7 to 9, the first conductive layer 22 is patterned so as to form a first circuit. In the embodiment, the method for patterning is described as follows. First, a first dry film 31 is formed on the first conductive layer 22. Afterward, the first dry film 31 is exposed and developed so as to form a plurality of openings 32, as shown in FIG. 7. Afterward, the first conductive layer 22 in the openings 32 is etched so as to form the first circuit, as shown in FIG. 8. Finally, the first dry film 31 is removed so as to expose the first circuit of the first conductive layer 22, as shown in FIG. 9. The first circuit comprises at least one first power/ground plane 222 and a plurality of conductive traces (a plurality of first conductive traces 28A and a plurality of second conductive traces 28B) (FIG. 11). Preferably, the second conductive layer 23 is patterned so as to form a second circuit by the method described above, and the second circuit comprises at least one second power/ground plane 231.

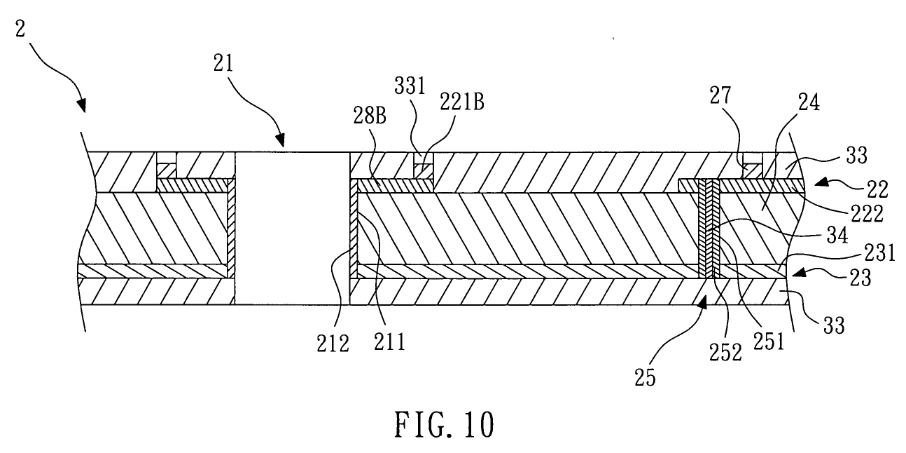

As shown in FIG. 10, a solder mask 33 is formed to cover the first conductive layer 22 and the second conductive layer 23. The solder mask 33 further covers the second through hole 251, and does not cover the first through hole 211. Preferably, the second through hole 251 is filled with an insulating material 34 (which is different from the solder mask 33). Afterward, the solder mask 33 is patterned so as to form an opening pattern 331, and the opening pattern 331 exposes part of the first circuit. Afterward, a plurality of fingers (a plurality of first fingers 221A and a plurality of second fingers 221B) (FIG. 11) are formed in the opening pattern 331. Preferably, the fingers (the first fingers 221A and the second is fingers 221B) are formed in the opening pattern 331 by electroplating. It is understood that a plurality of I/O ball pads 26 and a plurality of power/ground ball pads 27 (FIG. 11) are formed by the opening pattern 331.

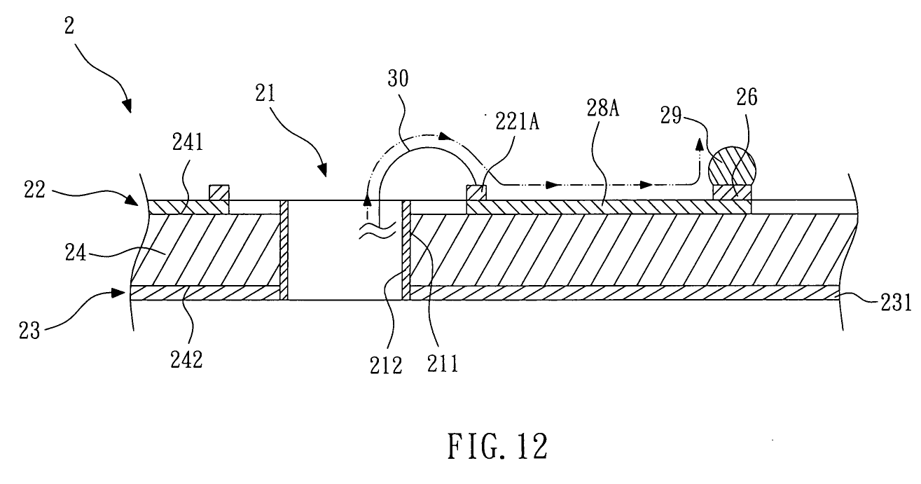

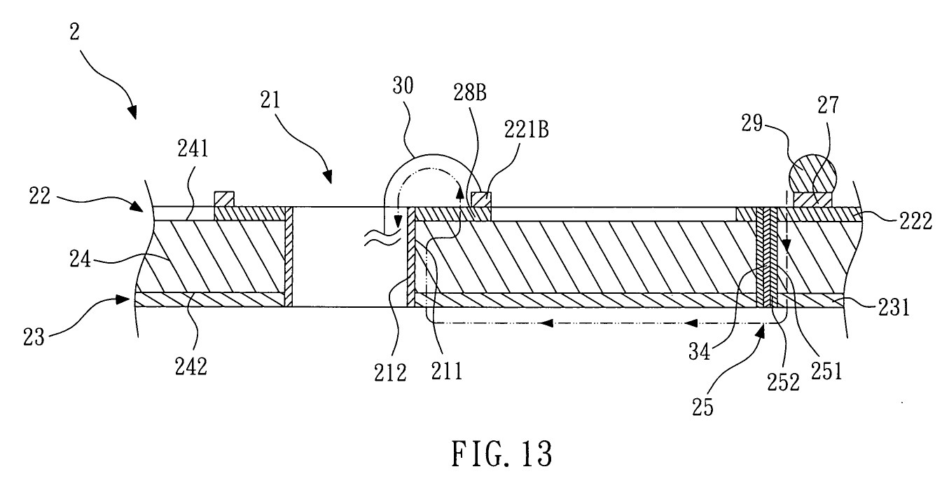

FIG. 11 shows a top view of a substrate of a window ball grid array package according to a first embodiment of the present invention, wherein a solder mask 33 is omitted. Also, referring to FIGS. 12 and 13, FIG. 12 shows a cross-sectional view along line 12-12 in FIG. 11, wherein solder balls and wires are added; FIG. 13 shows a cross-sectional view along line 13-13 in FIG. 11, wherein solder balls and wires are added. The substrate 2 comprises a core layer 24 (as shown in FIGS. 12 and 13), a first conductive layer 22, a second conductive layer 23 (as shown in FIGS. 12 and 13), at least one window 21 and at least one via 25.

The core layer 24 has a first surface 241 and a second surface 242. The first conductive layer 22 is disposed on the first surface 241 of the core layer 24. The second conductive layer 23 is disposed on the second surface 242 of the core layer 24.

The window 21 comprises a first through hole 211 and a third conductive layer 212. The window 21 is used for wire bonding to a chip (not shown). The first through hole 211 penetrates the core layer 24, the first conductive layer 22 and the second conductive layer 23. The first through hole 211 has a first sidewall. The third conductive layer 212 is formed on the first sidewall and connects the first conductive layer 22 and the second conductive layer 23. Preferably, the third conductive layer 212 is an electroplating layer.

The via 25 comprises a second through hole 251, a fourth conductive layer 252 and an insulating material 34. The via 25 is used for interconnection. The second through hole 251 penetrates the core layer 24, the first conductive layer 22 and the second conductive layer 23. The second through hole 251 has a second sidewall. The fourth conductive layer 252 is formed on the second sidewall, and electrically connects the first conductive layer 22 and the second conductive layer 23. The diameter of the first through hole 211 is larger than that of the second through hole 251. Preferably, the fourth conductive layer 252 is an electroplating layer.

In the embodiment, the first conductive layer 22 comprises a first circuit, the first circuit comprises at least one first power/ground plane 222, a plurality of fingers (a plurality of first fingers 221A and a plurality of second fingers 221B), a plurality of I/O ball pads 26, a plurality of power/ground ball pads 27 and a plurality of conductive traces (a plurality of first conductive traces 28A and a plurality of second conductive traces 28B).

The material of the first power/ground plane 222 is copper. In the embodiment, the power/ground ball pads 27 are disposed on the first power/ground plane 222. The first power/ground plane 222 connects the via 25. A plurality of solder balls 29 (as shown in FIGS. 12 and 13) are formed on the I/O ball pads 26 and the power/ground ball pads 27. The fingers (the first fingers 221A and the second fingers 221B) are disposed at the periphery of the window 21. In the embodiment, the fingers (the first fingers 221A and the second fingers 221B) are electrically connected to a chip (not shown) by a plurality of wires 30 (as shown in FIGS. 12 and 13).

The first fingers 221A are electrically connected to the I/O ball pads 26 by the first conductive traces 28A. The second fingers 221B are electrically connected to the third conductive layer 212 by the second conductive traces 28B.

The second conductive layer 23 comprises a second circuit, and the second circuit comprises at least one second power/ground plane 231 (as shown in FIGS. 12 and 13). In the embodiment, the material of the second power/ground plane 231 is copper.

FIGS. 12 and 13 show schematic views of the substrate of a window ball grid array package according to the present invention during operation. First, FIG. 12 shows a schematic view of a current of a signal. When the chip sends a signal, the signal current is transmitted to the first fingers 221A by the wires 30, and then transmitted to the I/O ball pads 26 by the first conductive traces 28A, and finally transmitted out by the solder balls 29.

FIG. 13 shows a schematic view of a return current. The return current is transmitted to the power/ground ball pads 27 by the solder balls 29, and then transmitted to the second power/ground plane 231 of the second conductive layer 23 by the first power/ground plane 222 of the first conductive layer 22 and the via 25. Afterward, the return current is transmitted to the first conductive layer 22 by the third conductive layer 212, and then transmitted to the second fingers 221B by the second conductive traces 28B, and finally transmitted back to the chip by the wires 30.

In the present invention, the third conductive layer 212 is disposed on the first sidewall of the first through hole 211 of the window 21, and electrically connects the second fingers 221B to the second power/ground plane 231. Since the second conductive layer 23 is a good conductor with a wide area, the return current passes through a path with low impedance on the second conductive layer 23 and then is transmitted to the second fingers 221B by the third conductive layer 212. As a result, the substrate 2 has the effect of controlling the characteristic impedance and increasing the signal integrity.

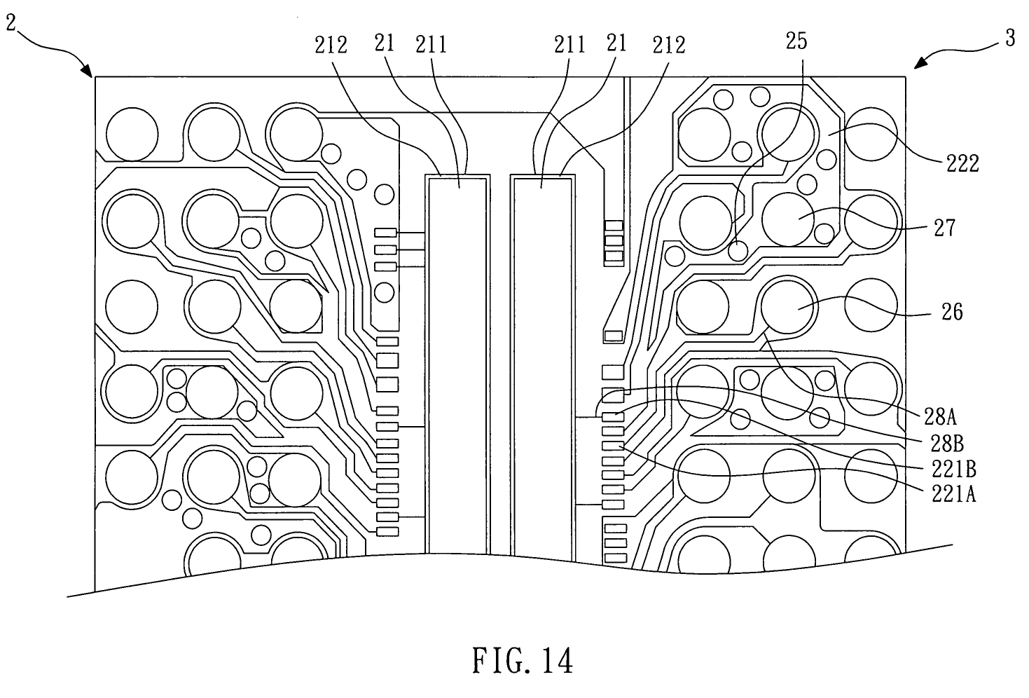

FIG. 14 shows a top view of a substrate for a window ball grid array package according to a second embodiment of the present invention. The substrate 3 according to the second embodiment is substantially the same as the substrate 2 (FIG. 11) according to the first embodiment, except for the amount of the window 21 and the third conductive layer 212. In the embodiment, the substrate 3 has two windows 21 and two third conductive layers 212. Each third conductive layer 212 surrounds each window 21. One of the two third conductive layers 212 is grounded or powered, or both of the third conductive layers 212 are grounded or powered.

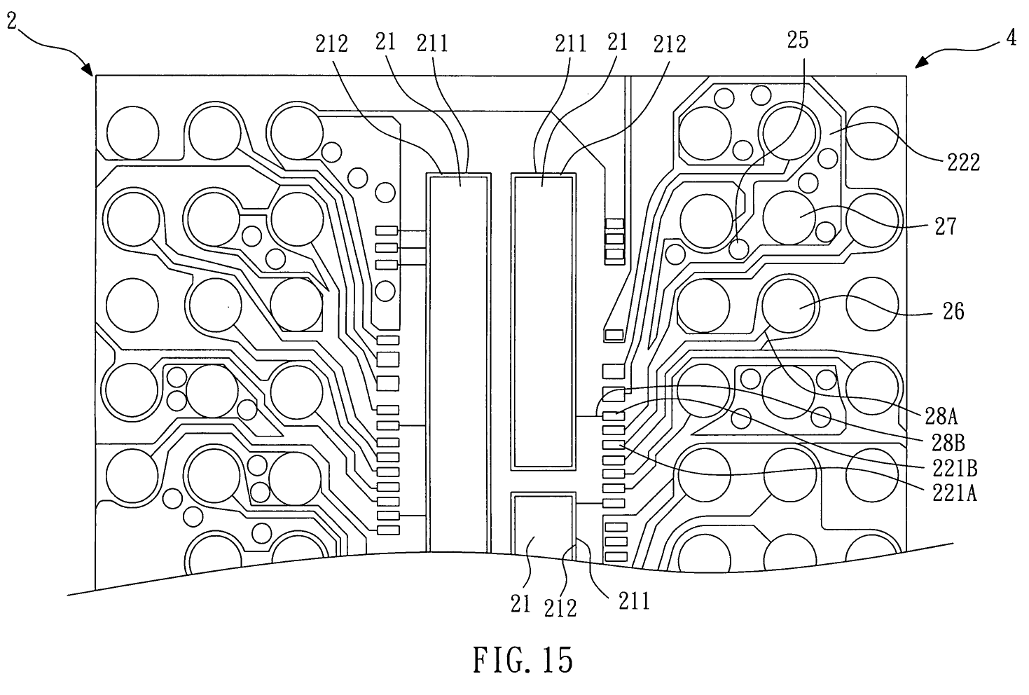

FIG. 15 shows a top view of a substrate for a window ball grid array package according to a third embodiment of the present invention. The substrate 4 according to the third embodiment is substantially the same as the substrate 2 (FIG. 11) according to the first embodiment, except for the amount of the window 21 and the third conductive layer 212. In the embodiment, the substrate 4 has three windows 21 and three third conductive layers 212. Each third conductive layer 212 surrounds each window 21. One of the three third conductive layers 212 is grounded or powered, or all of the third conductive layers 212 are grounded or powered.

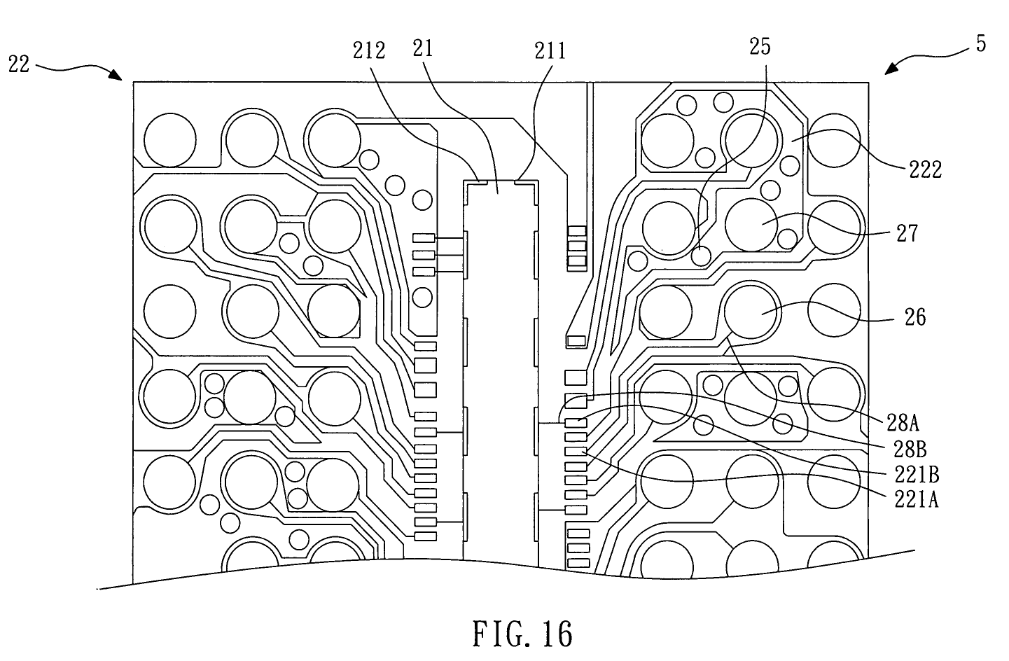

FIG. 16 shows a top view of a substrate for a window ball grid array package according to a fourth embodiment of the present invention. The substrate 5 according to the fourth embodiment is substantially the same as the substrate 2 (FIG. 11) according to the first embodiment, except for the form of the third conductive layer 212. In the embodiment, the third conductive layer 212 of the substrate 5 comprises a plurality of sections, and the sections are not connected to each other. One of the sections is grounded or powered, or all of the sections are grounded or powered.

While several embodiments of the present invention have been illustrated and described, various modifications and improvements can be made by those skilled in the art. The embodiments of the present invention are therefore described in an illustrative but not restrictive sense. It is intended that the present invention should not be limited to the particular forms as illustrated, and that all modifications which maintain the spirit and scope of the present invention are within the scope defined in the appended claims.

What is claimed is:

1. A method for making a substrate of a window ball grid array package, comprising:
(a) providing a substrate having a core layer, a first conductive layer and a second conductive layer;
(b) forming at least one first through hole and at least one second through hole, wherein the first through hole and the second through hole penetrate the substrate, the first through hole has a first sidewall, and the second through hole has a second sidewall;
(c) forming a third conductive layer on the first sidewall and a fourth conductive layer on the second sidewall;
(d) patterning the first conductive layer so as to form a first circuit;
(e) forming a solder mask on the first conductive layer and the second conductive layer;
(f) patterning the solder mask so as to form an opening pattern, wherein the opening pattern exposes part of the first circuit; and
(g) forming a plurality of fingers in the opening pattern.

2. The method as claimed in claim 1, wherein in Step (a), the material of the core layer is a dielectric material, and the material of the first conductive layer and the second conductive layer is copper.

3. The method as claimed in claim 1, wherein in Step (b), the first through hole and the second through hole are formed by drilling, and the diameter of the first through hole is larger than that of the second through hole.

4. The method as claimed in claim 1, wherein in Step (b), the first through hole is used for wire bonding to a chip, and the second through hole is used for interconnection.

5. The method as claimed in claim 1, wherein in Step (c), the third conductive layer is formed on the first sidewall by electroplating, and the fourth conductive layer is formed on the second sidewall by electroplating.

6. The method as claimed in claim 1, wherein in Step (c), the third conductive layer and the fourth conductive layer both connect the first conductive layer and the second conductive layer.

7. The method as claimed in claim 1, wherein Step (d) comprises:
(d1) forming a first dry film on the first conductive layer;
(d2) exposing and developing the first dry film so as to form a plurality of openings;
(d3) etching the first conductive layer so as to form the first circuit; and
(d4) removing the first dry film.

8. The method as claimed in claim 1, wherein Step (d) further comprises a step of patterning the second conductive layer so as to form a second circuit.

9. The method as claimed in claim 1, further comprising a step of filling the second through hole with an insulating material after Step (d).

10. The method as claimed in claim 1, wherein in Step (e), the solder mask further covers the second through hole, and does not cover the first through hole.

11. The method as claimed in claim 1, wherein in Step (g), the fingers are formed in the opening pattern by electroplating.

12. The method as claimed in claim 1, wherein in Step (g), a plurality of I/O ball pads and a plurality of power/ground ball pads are further formed in the opening pattern.

13. A substrate of a window ball grid array package, comprising:
a core layer, having a first surface and a second surface;
a first conductive layer, disposed on the first surface of the core layer;
a second conductive layer, disposed on the second surface of the core layer;
at least one window, each window comprising a first through hole and a third conductive layer, wherein the first through hole penetrates the core layer, the first conductive layer and the second conductive layer, the first through hole has a first sidewall, and the third conductive layer is formed on the first sidewall and connects the first conductive layer and the second conductive layer; and
at least one via, each via comprising a second through hole and a fourth conductive layer, wherein the second through hole penetrates the core layer, the first conductive layer and the second conductive layer, the second through hole has a second sidewall, and the fourth conductive layer is formed on the second sidewall and connects the first conductive layer and the second conductive layer.

14. The substrate as claimed in claim 13, wherein the first conductive layer comprises a first circuit, the first circuit comprises at least one first power/ground plane, a plurality of first fingers, a plurality of second fingers, a plurality of I/O ball pads, a plurality of power/ground ball pads, a plurality of first conductive traces and a plurality of second conductive traces, wherein the first fingers are electrically connected to the I/O ball pads by the first conductive traces, the power/ground ball pads are disposed on the first power/ground plane, the first power/ground plane connects the via, and the second fingers are electrically connected to the third conductive layer by the second conductive traces.

15. The substrate as claimed in claim 14, wherein the first fingers and the second fingers are electrically connected to a chip, and a plurality of solder balls are formed on the I/O ball pads and the power/ground ball pads.

16. The substrate as claimed in claim 13, wherein the second conductive layer comprises a second circuit, and the second circuit comprises at least one second power/ground plane.

17. The substrate as claimed in claim 13, wherein the material of the first conductive layer and the second conductive layer is copper, and the third conductive layer and the fourth conductive layer are electroplating layers.

18. The substrate as claimed in claim 13, wherein the window is used for wire bonding to a chip, and the via is used for interconnection.

19. The substrate as claimed in claim 13, wherein the third conductive layer comprises a plurality of sections, and the sections are not connected to each other.

20. The substrate as claimed in claim 13, comprising a plurality of windows.
